(19) United States
(12) Patent Application Publication
(10) Pub. No.: US 2011/0041908 A1
(43) Pub. Date: Feb. 24, 2011

(54) REAR-CONTACT SOLAR CELL HAVING ELONGATE, INTER-DIGITATED EMITTER AND BASE REGIONS ON THE REAR SIDE AND METHOD FOR PRODUCING THE SAME

(75) Inventor: Nils-Peter Harder, Hameln (DE)

Correspondence Address: BIRCH STEWART KOLASCH & BIRCH, PO BOX 747, FALLS CHURCH, VA, 22040-0747, US

(73) Assignee: INSTITUT FÜR SOLARENERGIEFORSCHUNG GMBH, Emmerthal (DE)

(21) Appl. No.: 12/747,415

(22) PCT Filed: Nov. 28, 2008
(86) PCT No.: PCT/EP2008/066432

§ 371 Date: Oct. 7, 2010

(30) Foreign Application Priority Data
Dec. 11, 2007 (DE) 10 2007 059 486.2

(51) Int. Cl. H01L 31/02; H01L 31/18

(52) U.S. Cl. 136/256; 438/57; 257/E31.111

(57) ABSTRACT

The invention relates to a rear-contact solar cell and to a method for producing the same, wherein elongate emitter regions (5) and elongate base regions (7) are defined in a semiconductor substrate (1) in a finely interleaved manner on the surface of the rear side of the cell. The elongate emitter regions (5) are contacted by elongate emitter contacts (11) that extend at a right angle thereto, and the elongate base regions (7) are contacted by elongate base contacts (13) that extend at a right angle thereto, the structural width of the emitter and base regions (5, 7) being substantially smaller than the structural width of the emitter and base contacts. The finely interleaved arrangement of emitter and base regions (5, 7) results in good current collecting properties and low series resistances within the semiconductor substrate. Owing to the less complicated structures of the metal contacts, the latter can be produced in a simple and reliable manner.

### FIELD OF THE INVENTION

The present invention relates to a rear-contact solar cell having elongate, inter-digitated emitter and base regions on the rear side and also to a method for producing a rear-contact solar cell of this type.

### BACKGROUND TO THE INVENTION

Conventional solar cells have a front side contact, that is to say a contact arranged on a surface of the solar cell that faces the light, and a rear side contact on a surface of the solar cell that is turned away from the light. In these conventional solar cells, the largest volume fraction of a semiconductor substrate absorbing the light is of precisely the semiconductor type (for example p type) which is contacted by the rear side contact. This volume fraction is conventionally referred to as the base and the rear side contacts are therefore conventionally referred to as base contacts. A thin layer of the opposite semiconductor type (for example n type) is located in the region of the surface of the front side of the semiconductor substrate. This layer is conventionally referred to as the emitter and the contacts contacting it are referred to as emitter contacts.

In conventional solar cells of this type, the pn junction, which is crucial for the collection of current, is thus positioned just under the front side surface of the solar cell. This position of the pn junction is advantageous for an efficient collection of current in particular on use of semiconductor material of poor to moderate quality, as the highest generation rate of charge carrier pairs is present on the side of the solar cell that faces the light and most light-generated (minority) charge carriers thus have to cover only a short distance to the pn junction.

However, the emitter contacts arranged on the front side of the solar cell lead, on account of the partial shading associated therewith of the front side, to a loss in efficiency. In order to increase the efficiency of the solar cell, it is basically advantageous to arrange both the base contacts and the emitter contacts on the rear side of the solar cell. For this purpose, corresponding emitter regions have to be formed on the rear side of the solar cell. A solar cell in which both emitter regions and base regions are located on the side which is turned away from the light during use and in which both the emitter contacts and the base contacts are formed on the rear side is referred to as a rear-contact solar cell.

Rear-contact solar cells of this type, the current-collecting pn junction of which is arranged at least partly on the rear side of the solar cell, have to deal with the problem that both the emitter regions and the base regions are arranged next to one another on the rear side of the solar cell. Thus, the pn junction can no longer be formed along the entire surface of the solar cell; instead, the rear side emitter regions forming the pn junction together with the volume base region can now be formed only on a part of the rear side surface of the solar cell. Rear side base regions have to be provided therebetween for contacting the base.

An example of a conventional rear-contact solar cell is illustrated in cross section in FIG. 7. A semiconductor substrate 101 forms in its volume a base region for example of the p semiconductor type. Emitter regions 105 are formed on a rear side surface 103. The emitter regions 105 cover the majority of the rear side surface 103. Narrow, line-shaped regions, at which base regions 107 of the semiconductor substrate 101 reach up to the rear side surface 103, are left free between the elongate, finger-shaped emitter regions 105. The rear side surface 103 is covered with a dielectric passivating layer 109 which can have a low index of refraction, so that it can serve for example as a rear side reflector for the solar cell, and which can for example be formed from silicon dioxide. The passivating layer 109 has local openings 111 through which emitter contacts 113 can contact the emitter regions 105. Furthermore, the dielectric layer 109 has openings 115 through which base contacts 117 can contact the base regions 107 which reach locally up to the rear side surface. The emitter contacts 113 and the base contacts 117 are separated from one another by narrow gaps 119 and thus electrically insulated.

FIG. 8 is a plan view onto the rear side of the conventional rear-contact solar cell illustrated in FIG. 7. It may be seen how elongate, finger-shaped emitter and base contacts 113, 117 are arranged inter-digitated in a comb-like manner. The emitter contacts 113 have in this case a much greater width than the base contacts 117. At their lateral ends, the emitter contacts 113 lead into current-collecting emitter busbars 121 which are formed as widenings of the emitter metal coating at an edge of the solar cell. Accordingly, the base contacts 117 lead into base busbars 123 at the opposing edge of the rear side of the cell.

In the described conventional rear-contact solar cell, there is the following optimisation problem: for effective collection of the charge carriers generated by light in the base substrate 101, an emitter region 105 which is as extensive as possible, that is to say a pn junction which is as extensive as possible, is advantageous so that the minority charge carriers generated have short distances to the pn junction and can be collected before they recombine. However, in this conventional solar cell design, an extensive emitter implies long distances for the majority charge carriers within the base substrate 101. This can lead to resistance losses, in particular in lightly doped base substrates displaying low conductivity. A cell optimisation must therefore take place in the trade-off between optimum current collection and minimising series resistance.

These problems are intensified under the busbars 121, 123 of the solar cell in which the finger-shaped contacts 113, 117 are combined. In this case, the busbars carry the sum of the current of a plurality of contact fingers up to the current pick-up points, the “solder pads”. As the current intensity is high here, the busbars have to be configured, as shown in FIG. 8, so as to be wider than the contact fingers. In particular under the emitter busbar 121, the series resistance problem therefore increases greatly and can thus reduce the efficiency of the solar cell as a whole. A reduced current-collecting capacity can also occur in the region of the busbar 123, where there is no emitter in this conventional cell design; this can also lead to negative effects on the efficiency of the solar cell as a whole. In addition, the losses mentioned for the emitter busbar and the base busbar occur in intensified form under the widened regions of the busbars which serve as solder pads.

A further aspect to be taken into account in the optimisation of rear-contact solar cells is the fact that, in order to minimise production costs, the emitter contacts 113 and the base contacts 117 are generally applied in a common method step, for example by vapour depositing of metal. Both contact types are thus of substantially uniform thickness. However, in the rear-contact solar cell shown in FIGS. 7 and 8, the base contacts 117 are much narrower than the emitter contacts 113. However, as both contacts 113, 117 have to discharge the same current, it is the case that the emitter contacts are much thicker than required when applying a metal layer thickness for the contacts that is sufficient for an efficient dissipation of current from the base through the base contacts. In other words, an unnecessarily large amount of material is deposited on the more extensive emitter contacts when base and emitter contacts are deposited in a common process step. However, the application of the metal coating for the contacts and also the associated material costs are a considerable portion of the total costs of the solar cells.

It may therefore be desirable to form the metal contacts for both the emitter and the base contacts in roughly the same width and in this case to preferably make both contact types as wide as possible, so that an electrical resistance in the metal contacts that is as low as possible can be achieved at a low metal layer thickness.

Rear-contact solar cells such as are illustrated schematically in FIG. 9 were developed in an attempt to satisfy the above-described, partly contradictory requirements placed on a rear-contact solar cell. These rear-contact solar cells have very fine structures both for the base and emitter regions 205, 207 and for the base and emitter contacts 213, 217. The structural widths are in this case typically between 5 μm and 100 μm.

The illustrated solar cell type has only narrow emitter regions 205 forming the current-collecting pn junction. Narrow base regions 207 are positioned in each case therebetween. In this way, it is possible to ensure that the majority charge carriers have to cover only short distances in the interior of the semiconductor substrate 201 up to the base regions 207 and then to the base contacts 217. At the same time, the short distance between adjacent emitter regions 205 ensures that the minority charge carriers have to travel only short distances to a current-collecting pn junction, allowing good current-collecting efficiency to be ensured.

Nevertheless, it has been found that it may be a major technological challenge, in particular for cost-effective large-scale production of extensive rear-contact solar cells, to correctly produce both emitter and base regions and emitter and base contacts with such fine structures having widths of from 5 to 100 μm. On a laboratory scale, high-precision methods such as for example photolithography are frequently used for this purpose. These manufacturing methods have to be carried out with very high reliability, as even individual errors, in particular in the contact separation between adjacent fingers of the emitter and base contacts, can lead to considerable damage to the solar cell. Correspondingly finely structured rear-contact solar cells have therefore proven largely unsuitable for major industrial large-scale manufacture of inexpensive solar cells.

A further problem with the finely structured rear-contact solar cell from FIG. 9 may consist in the fact that, on account of the small structural widths, the gaps 219, which must necessarily be provided between adjacent emitter and base contacts 213, 217 for electrical insulation, can take up a considerable portion of the rear side surface area of the solar cell. Accordingly, the thickness of the contact fingers has to be selected so as to be correspondingly high in order to provide a sufficiently large amount of metal, so that a low series resistance can be achieved for the lateral conveyance of current. The production of such narrow and at the same time high metal contacts is technologically difficult or entails increased costs, in particular in coating methods such as sputtering or electroplating.

### SUMMARY OF THE INVENTION

There may therefore be a need for a rear-contact solar cell and for a method for producing a rear-contact solar cell in which the above-mentioned problems of conventional rear-contact solar cells can be at least partly solved. In particular, there may be a need for a rear-contact solar cell which, on the one hand, displays good current-collecting properties and which, on the other hand, allows low series resistances within the base. It may in this case be desirable for a solar cell of this type to be able to be produced in a technologically simple, reproducible and reliable manner and at low costs.

This need can be met by the subject matter of the independent claims. Advantageous embodiments of the present invention are described in the dependent claims and also in the following description.

A first aspect of the present invention describes a rear-contact solar cell having a semiconductor substrate, elongate emitter regions on a rear side surface of the semiconductor substrate, elongate base regions on the rear side surface of the semiconductor substrate, elongate emitter contacts transverse to the elongate emitter regions for electrically contacting the emitter regions and elongate base contacts transverse to the elongate base regions for electrically contacting the base regions. The semiconductor substrate preferably has a base semiconductor type which may be either an n semiconductor type or a p semiconductor type. The elongate base regions on the rear side surface also have the base semiconductor type. The emitter regions have an opposite emitter semiconductor type to the base semiconductor type. The elongate emitter regions have smaller structural widths than the elongate emitter contacts and the elongate base regions have smaller structural widths than the elongate base contacts.

This first aspect of the present invention may be regarded as being based on the following idea: Both narrow elongate base regions and narrow elongate emitter regions are formed on the rear side surface of the solar cell, wherein the base and emitter regions can be formed so as to adjacently adjoin one another and mesh with one another in a comb-like manner. Elongate emitter and base contacts are provided in order to electrically contact the respective emitter and base regions. The emitter and base contacts each run transversely to the emitter and base regions and can traverse the emitter and base regions at least in partial regions of the rear side of the solar cell. Suitable measures, such as will be presented in greater detail hereinafter by way of example and with reference to preferred embodiments, can ensure that the emitter contacts contact exclusively the emitter regions, but not the base regions and that, conversely, the base contacts contact exclusively the base regions, but not the emitter regions.

The proposed cell design allows inter alia the structural widths of the emitter and base contacts to be selected independently of those of the emitter and base regions. In this way, the optimisation of the solar cell can take account of the partly contradictory requirements placed on the geometrical arrangement and on the structural widths of the emitter and base regions, on the one hand, and the emitter and base contacts, on the other hand. Now, it has proven advantageous to select the structural widths of the emitter and base regions so as to be less than the structural widths of the emitter and base contacts. On the one hand, both good current-collecting properties and low series resistance losses within the base can be achieved as a result of narrow and closely adjacent emitter regions and narrow and likewise closely adjacent base regions running therebetween. On the other hand, simple and reliable production of the contacts can be achieved as a result of comparatively wide emitter and base contacts. In addition, the emitter and base contacts can be formed so as to be roughly the same size in terms of area, so that both contact types can be formed with the same thickness in a common process step without one of the contact types having a wastefully high thickness based on its area and without, in the other case, one of the contact types constituting, at a given thickness of the metal coating, an excessively high electrical resistance on account of its lower width.

Further features, details and possible advantages of embodiments of the rear-contact solar cell according to the invention will be described hereinafter.

The semiconductor substrate used for the rear-contact solar cell may for example be a monocrystalline or multicrystalline silicon wafer. Alternatively, thin layers made of amorphous or crystalline silicon or of other semiconducting materials can be used as the substrate.

The elongate emitter regions can be produced by diffusing dopants into the semiconductor substrate. For example, an n-type emitter region can be produced in a p-type semiconductor substrate by local diffusion of phosphorus. However, alternatively, the emitter regions can also be produced by other methods such as for example by ion implantation or alloying, thus producing what is known as a homojunction, that is to say a pn junction with oppositely doped regions of the same semiconductor basic material, for example silicon. Alternatively, the emitter regions can also be deposited epitaxially, for example by vapour depositing or sputtering-on, thus producing homojunctions or what are known as heterojunctions, that is to say in the latter case pn junctions between a base semiconductor-type first semiconductor material and an emitter semiconductor-type second semiconductor material. A possible example are emitter regions made of layers of amorphous silicon (a-Si), applied by means of PECVD technology, on a semiconductor substrate made of crystalline silicon (c-Si).

Either the elongate base regions on the rear side surface of the semiconductor substrate may be regions which were omitted in the production of the emitter regions in the semiconductor substrate and have thus remained of the base semiconductor type, or they can be produced by means of one of the production methods described above for producing the emitter regions.

Photolithography methods can for example be used for producing the fine emitter and base regions. Alternatively, corresponding masks, which can be produced for example by laser structuring, can be used.

The elongate emitter regions and/or the elongate base regions can have an additional layer, for example made of ITO (indium tin oxide), for enhancing lateral conductivity.

A complementary manner, which is beneficial for the mode of operation of the solar cell, of arranging the base and emitter regions on the rear side of the solar cell can be produced in a technologically simple manner in that emitter (or base) is firstly produced over the entire area of the rear side of the solar cell and subsequently base (or emitter) regions, which locally overcompensate for the former emitter (or base) layer applied over the entire area, are subsequently produced at the desired points by locally introducing doping materials by for example ion implantation or diffusion of doping materials through for example a structured diffusion mask.

A further alternative is to firstly produce an emitter region, for example, over a large area, wherein the emitter region can subsequently be formed into finer structural widths as a result of the local removal of partial regions, for example by means of a laser.

The emitter regions and the base regions can each be formed, viewed from above onto the rear side surface of the semiconductor substrate, as a comb-like structure in which in each case finger-like, linear emitter regions adjoin adjacent finger-like, linear base regions. A nested structure of this type is also said to be “interdigitated”. The comb-like structure does not need to be formed in the same manner over the entire surface of the cell. It can be adapted to particular features in specific regions of the cell surface. For example, a different structure can be selected in regions below the base busbar to that in regions below the emitter busbar. Furthermore, this structure may also be present purely exclusively at specific locations of the cell, for example in the region of the busbars or solder pads.

Both the emitter contacts and the base contacts can each be formed in the form of a local metal coating, for example in the form of finger-like grids. For this purpose, metals, such as for example silver or aluminium, can be deposited on the rear side surface of the solar cell locally, for example through a mask or using photolithography, for example by vapour deposition or sputtering-on or else by using screen printing or a dispensing method. Generally, use may be made of all methods which allow contacts to be formed locally, for example in a finger or grid-shaped manner, on a rear side of a substrate, including the possibility of applying over the entire area metal layers which are subsequently structured by local removal. In order to avoid short circuits between the emitter contacts and the base contacts, a respective electrically insulating gap can be provided between the two.

According to one embodiment of the present invention, an averaged structural width of the elongate emitter regions and/or the elongate base regions is at least 10%, preferably at least 20% and more preferably at least 50% less than an averaged structural width of the elongate emitter contacts and/or the elongate base contacts. For example, the emitter and base regions can have structural widths in the range of from 5 to 500 μm and the emitter and base contacts can have correspondingly higher structural widths in the range of from 200 μm to 2 mm.

The structural widths of the emitter and base regions can for example be selected in such a way that the averaged distance between adjacent emitter regions, which in the case of nested structures corresponds roughly to the structural width of the base regions, is less than or substantially equal to the effective minority charge carrier diffusion length in the semiconductor substrate, so that light-generated charge carriers can be collected efficiently at the pn junctions formed by the emitter regions. On the other hand, the averaged structural width of the emitter regions, which corresponds substantially to the distance between adjacent base regions, can be selected in such a way that series resistances are kept as low as possible with respect to majority charge carriers drifting to the base regions.

The structural widths of the emitter and base contacts can be selected in such a way that, on the one hand, the contacts can be produced in a technologically simple manner and in particular a contact separation between emitter and base contacts can be reliably ensured and that, on the other hand, the distances between adjacent elongate emitter contacts or base contacts are small enough, so that charge carriers do not need to travel any wide lateral distances through lightly doped base regions up to a contact and so that the conveyance of the electrical charge carriers along the at least partly elongate and relatively highly doped emitter and base regions up to a respective contact does not produce any substantial series resistance losses.

According to a further embodiment of the present invention, a plurality of elongate emitter regions and a plurality of elongate base regions are each arranged alternately adjoining one another and parallel to one another and a plurality of elongate emitter contacts and a plurality of elongate base contacts are each arranged alternately and parallel to one another. The centre-to-centre distance between adjacent emitter and base regions is in this regard less than the centre-to-centre distance between adjacent emitter and base contacts.

In other words, the emitter and base regions, like the emitter and base contacts, can each be formed as mutually meshing structures, a degree of meshing, which can be defined as a number of adjacent regions or contacts for each unit area, being greater for the emitter and base regions than for the emitter and base contacts.

According to a further embodiment of the present invention, elongate emitter contacts traverse elongate base regions, the elongate base regions being insulated from the elongate emitter contacts traversing them by an electrically insulating layer.

In other words, at least some of the elongate emitter contacts can run at least in partial regions transversely, for example perpendicularly, over base regions positioned thereunder. In order to prevent local short circuits in the solar cell in this case, the emitter contacts are insulated there from the base regions running thereunder by an electrically insulating layer. The electrically insulating layer may for example be a dielectric layer, for example made of silicon nitride or silicon oxide, applied to the rear side surface of the semiconductor substrate or else a layer made of an organic resist. The layer can for example firstly be applied to the entire area of the rear side surface and then be locally opened at the location at which an electrical connection is to be produced between a contact and an emitter or base region positioned thereunder.

According to a further embodiment of the present invention, the rear-contact solar cell is formed in such a way that an electrical conductivity is higher in the elongate base regions on the rear side surface of the semiconductor substrate than in base regions in the interior of the semiconductor substrate.

In other words, the elongate base regions are not merely regions in which no emitter doping has been carried out and which therefore have the same doping as the original semiconductor substrate. Instead, the base regions can display an increased doping concentration, compared to the semiconductor substrate, of the base semiconductor type, for example more than 1*10¹⁸ cm⁻³, preferably more than 1*10¹⁹ cm⁻³, more preferably more than 5*10¹⁹ cm⁻³ and even more preferably more than 1*10²⁰ cm⁻³, and thus increased conductivity. For example, the elongate base regions can be produced by an additional diffusion process step in which dopants are diffused locally on the rear side of the semiconductor substrate for producing the base semiconductor type.

An increased conductivity within the elongate base regions allows majority charge carriers to be conducted with only low series resistance losses or over comparatively long distances without substantial resistance loss along the highly conductive elongate base regions up to the base contacts running transversely thereto.

In particular when, in accordance with a further preferred embodiment, the emitter regions and the base regions are distributed substantially homogeneously along the rear side surface of the semiconductor substrate, i.e. for example are so finely distributed that the distances between the relatively highly doped rear side base regions are small preferably over the entire rear side surface of the solar cell, this means that majority charge carriers throughout the base-like main volume of the semiconductor substrate have to travel just short distances before they reach a highly conductive elongate base region where they can then be conducted to the base contacts without further substantial series resistance losses. This allows the total series resistance of the solar cell to be reduced. The term “a preferably homogeneous distribution of fine elongate base or emitter regions” refers in this case to the fact that the distances between the rear side, relatively highly doped base regions are sufficiently short, so that no substantial drop in voltage occurs between the rear side base regions in the semiconductor substrate at the anticipated short circuit current densities of the solar cell and the resistance, which is defined by the substrate thickness, doping and charge carrier mobility, of the substrate. Structural widths of the emitter regions and the base regions can in this case be of the same size; however, alternatively, the emitter regions can also be selected so as to be wider than the base regions in order to form a charge carrier-collecting pn junction which is as extensive as possible.

A further aspect of the present invention describes a method for producing a rear-contact solar cell having the following steps: providing a semiconductor substrate of the base semiconductor type; forming elongate emitter regions of the emitter semiconductor type on a rear side surface of the semiconductor substrate; forming elongate base regions of the base semiconductor type on the rear side surface of the semiconductor substrate; forming elongate emitter contacts transversely to the elongate emitter regions for electrically contacting the emitter regions; forming elongate base contacts transversely to the elongate base regions for electrically contacting the base regions. The elongate emitter regions have in this case smaller structural widths than the elongate emitter contacts and the elongate base regions have smaller structural widths than the elongate base contacts.

The emitter regions and the base regions can be produced by means of different methods, for example by locally diffusing-in using for example masks or lithography, by ion implantation, by local alloying-in, by epitaxial application of corresponding layers, etc.

The emitter and base contacts can also be formed by means of various methods, for example by local vapour deposition, for example using masks or lithography, or by sputtering-on or else by using screen printing or dispensing methods. Generally, use may be made of all methods allowing contacts to be formed locally, for example in a finger or grid-shaped manner, on a rear side of a substrate, including the possibility of applying over the entire surface area metal layers which are subsequently structured by local removal. That means inter alia that the contacts can also firstly be formed as a common metal layer covering the entire rear side surface, wherein a contact separation between the emitter and base regions can subsequently be achieved, for example by local removal of metal, for example by etching-away or lasering-away.

It should be noted that the embodiments, features and advantages of the invention have been described mainly in relation to the rear-contact solar cell according to the invention. However, a person skilled in the art will recognise from the foregoing and also from the following description that, unless otherwise indicated, the embodiments and features of the invention are also similarly transferable to the method according to the invention for producing a solar cell. In particular, the features of the various embodiments may also be combined with one another in any desired manner.

### BRIEF DESCRIPTION OF THE DRAWINGS

Further features and advantages of the present invention will become apparent to the person skilled in the art from the following description of exemplary embodiments (although these are not to be interpreted as restricting the invention) and with reference to the accompanying drawings.

FIG. 1 is a plan view onto the rear side of a rear-contact solar cell according to one embodiment of the present invention.

FIG. 2 is a plan view onto the contact structure of the embodiment illustrated in FIG. 1.

FIG. 3 is a cross-sectional illustration along the plane A-A from FIG. 1.

FIG. 4 is a cross-sectional illustration along the plane B-B from FIG. 1.

FIG. 5 is a plan view onto the rear side of a rear contact solar cell according to a further embodiment of the present invention.

FIG. 6 is a plan view onto the rear side of a rear contact solar cell according to a further embodiment of the present invention.

FIG. 7 is a cross-sectional illustration of a conventional rear-contact solar cell.

FIG. 8 is a plan view onto the rear side of the conventional rear-contact solar cell from FIG. 7.

FIG. 9 is a cross-sectional illustration of a further conventional rear-contact solar cell.

All the figures are merely schematic and not true-to-scale. In the figures, similar or identical elements are denoted by the same reference numerals.

### DETAILED DESCRIPTION OF PREFERRED EMBODIMENTS

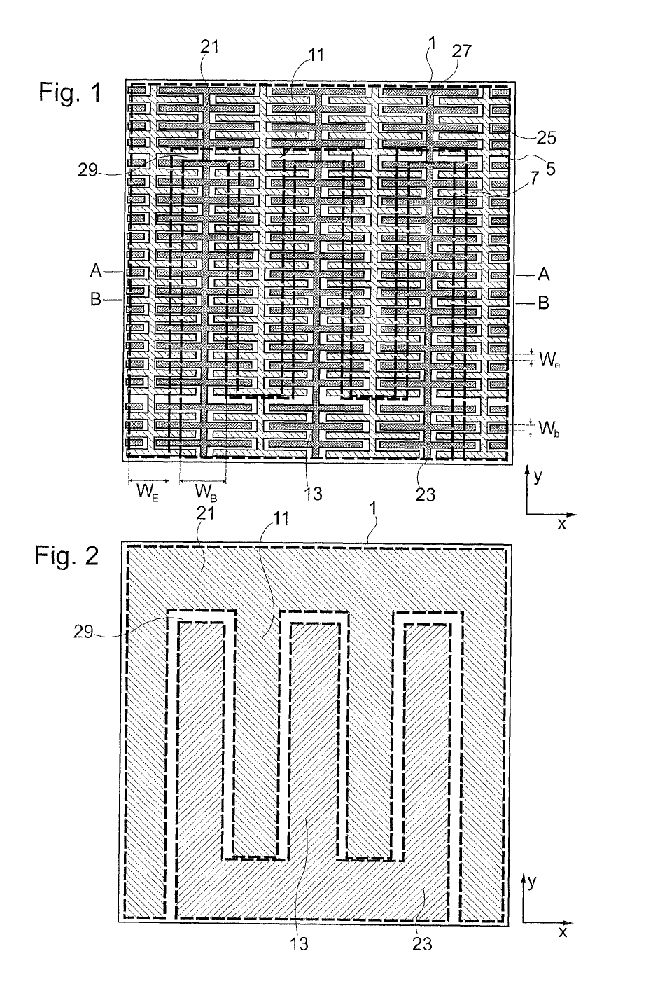

FIG. 1 shows one embodiment of a rear-contact solar cell in plan view onto the rear side thereof. For illustrative reasons, the emitter and base contacts 11, 13 have been presented in transparent form, with a dashed border, so that the emitter and base regions 5, 7 positioned thereunder may be seen. For the sake of clarity, the structure of the emitter and base contacts 11, 13 is shown again separately in FIG. 2. Just four emitter contact fingers have been shown, although it goes without saying that a real solar cell has a large number of emitter contact fingers of this type and that the dimensions thereof are not represented true-to-scale in the figures either.

As may be seen in FIG. 1, elongate, finger-shaped emitter contacts 11, which run parallel to one another substantially along the entire rear side surface, are located on the rear side surface of a semiconductor substrate 1. The emitter contact fingers 11 lead at an edge of the solar cell into an emitter busbar 21 running transversely to the fingers 11.

Offset from the emitter fingers 11, a plurality of base contact fingers 13 extended parallel to one another and so as to mesh with the emitter contact fingers. The base contact fingers lead into a base busbar 23 at the opposing edge of the solar cell.

Transversely to the emitter and base contact fingers 11, 13 running in the y direction in the drawing, elongate emitter regions 5 and elongate base regions 7 run on the rear side surface 3 of the semiconductor substrate 1. Elongate emitter regions 5 running parallel to one another and also base regions 7 running parallel to one another are each joined together at their centre by connecting pieces 25, 27 running transversely to the regions 5, 7, so that a herringbone pattern is produced in each case. The elongate emitter and base regions run in the x direction in the drawing, that is to say orthogonally to the direction of the emitter and base contact fingers 11, 13.

A structural width W_{E}, W_{B} of the emitter and base contact fingers respectively is roughly three to four times as large as a structural width Wₑ, W_{b} of the emitter and base regions 5, 7 respectively running transversely thereto.

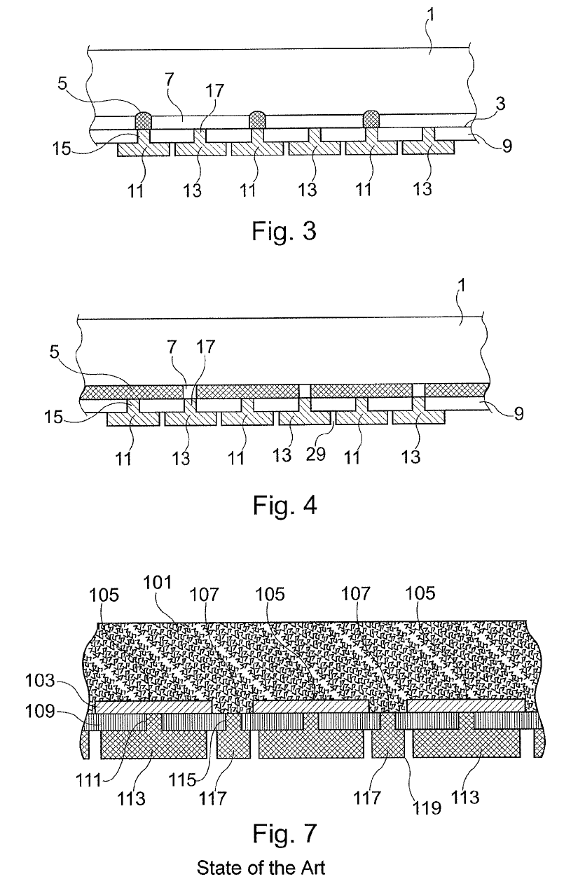

As may be seen in FIGS. 2 and 3, the emitter and base contacts 11, 13 are separated in wide regions of the rear side surface 3 from the emitter regions 5 and the base regions 7 by an electrically insulating layer 9 in the form of a dielectric layer. The contacts 11, 13 can locally contact the regions 5, 7 positioned thereunder merely at openings 15, 17 in the insulating layer 9.

Both the emitter regions 5 and the base regions 7 were diffused into the semiconductor substrate 1 at the rear side thereof and show an increased conductivity on account of an increased dopant concentration. As the emitter regions 5 protrude laterally, in the x direction beyond a region covered by the emitter contact 11 positioned thereover, even into the area of the adjacent base contact 13, there too charge carriers can be efficiently collected on account of the pn junction which is produced and then be conducted toward the emitter contact 11 along the highly doped emitter regions 5 with low serial resistance losses. The same applies to the base contacts 13 and the base regions 7. Both good collecting properties and low series resistances can thus be achieved on account of the fine meshing of the emitter and base regions 5, 7.

Compared to the emitter and base regions 5, 7, the emitter and base contacts 11, 13 have a much coarser mesh. Such coarse structures of the metalization, having orders of magnitude for example in the range of more than one millimetre, can be produced in a technologically simple and reliable manner, in particular as the gap 29 between the emitter contacts 11 and base contacts 13 can therefore be formed so as to be comparably wide, for example having a width of a few 100 μm, without substantial loss of metalized area; this ensures reliable insulation between the contacts.

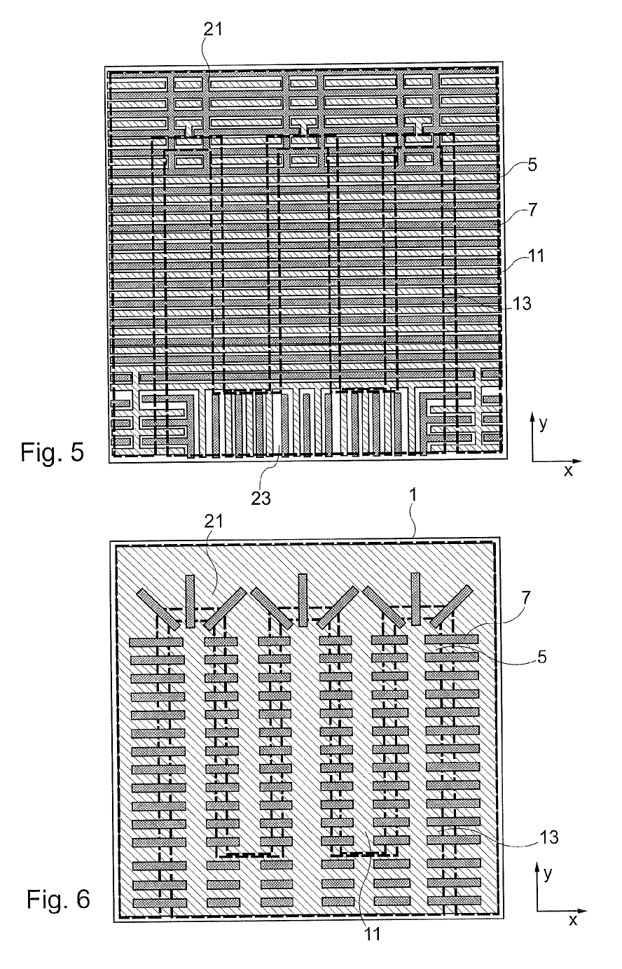

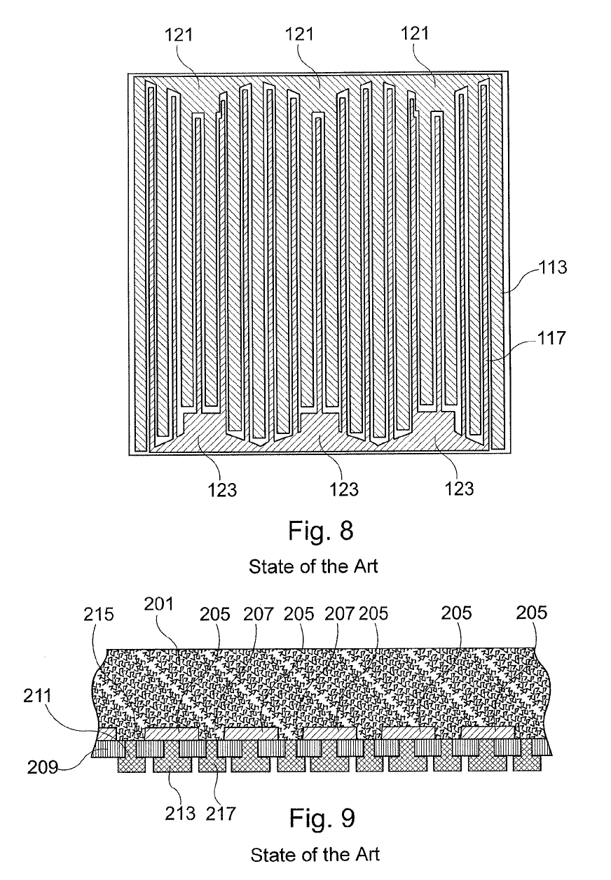

FIG. 5 shows an alternative embodiment of a solar cell according to the invention in a plan view onto the rear side thereof. In this embodiment, the pattern consisting of emitter regions 5 and base regions 7 is kept very simple at least in regions outside the busbars 21, 23, namely in the form of alternately arranged elongate, narrow regions 5, 7 which are reminiscent of the pattern of a zebra crossing. The mutually adjacent emitter and base regions 5, 7 respectively are in this case no longer joined together in the y direction by additional connecting regions within the semiconductor substrate. Instead, an electrical connection of this type takes place merely as a result of the emitter and base contacts 11, 13 respectively which run transversely thereto and each locally contact the individual emitter and base regions 5, 7 respectively.

FIG. 6 shows a further embodiment in which the emitter covers a large part of the rear side surface and elongate base regions 7, which extend into the regions below the emitter contacts 11, are located merely in partial regions in the region at the edge of the base contacts 13. The heavily doped base regions 7 can thus discharge even majority charge carriers which were generated in the regions of the emitter contacts 11 toward the base contacts 13 without substantial series resistance losses. Between the elongate base regions 7 extend likewise elongate emitter regions 5. In the region of the tips of the fingers of the base contacts 13, elongate emitter regions fingers 47 protrude partly obliquely to well under the region of the emitter busbar 21 in order to be able to discharge charge carriers from there too with low losses.

In the embodiment illustrated in FIG. 6, the design of the elongate emitter and base regions 5, 7 running transversely to the elongate contacts 11, 13 has been implemented in an especially optimised manner. On the one hand, only a small number of elongate base regions are necessary, so that the production of these regions is simple to carry out. On the other hand, these regions are provided precisely in those areas in which they contribute in a targeted manner to the efficient, low-loss discharge of charge carriers from regions below the emitter contacts 11 and emitter busbars 21. The elongate emitter regions 5 running between the elongate base regions 7 are in this case at the same time an effectively conductive connection to the emitter regions, which form the pn junction and thus collect current, under the base contacts 13 and base busbars 23.

It will be clear to the person skilled in the art from the foregoing description that the principle underlying the invention can be implemented by a large number of specific configurations. In particular the configuration of the emitter and base regions and also the emitter and base contacts, with regard to their geometry and arrangement and also with regard to the production thereof, can be markedly varied without departing from the basic idea of the invention, such as it is described in the independent claims.

Finally, reference is made to the fact that the terms “comprising”, “have”, etc. do not rule out the presence of further elements. The term “a(n)” does not rule out the presence of a plurality of items either. The reference numerals in the claims serve merely to improve readability and are not in any way intended to restrict the scope of protection of the claims.

1.-10. (canceled)

11. Rear-contact solar cell, having:
a semiconductor substrate;
elongate base regions on the rear side surface of the semiconductor substrate, the base regions having a base semiconductor type;
elongate emitter regions on a rear side surface of the semiconductor substrate, the emitter regions having an emitter semiconductor type opposite to the base semiconductor type;
elongate emitter contacts transverse to the elongate emitter regions for electrically contacting the emitter regions;
elongate base contacts transverse to the elongate base regions for electrically contacting the base regions;
wherein the elongate emitter regions have smaller structural widths than the elongate emitter contacts and wherein the elongate base regions have smaller structural widths than the elongate base contacts.

12. Rear-contact solar cell according to claim 11, wherein an averaged structural width of the elongate emitter regions and/or of the elongate base regions is at least 10% less than an averaged structural width of the elongate emitter contacts and/or of the elongate base contacts in the same area region of the solar cell.

13. Rear-contact solar cell according to claim 11, wherein a plurality of elongate emitter regions and a plurality of elongate base regions are each arranged alternately adjoining one another and parallel to one another and wherein a plurality of elongate emitter contacts and a plurality of elongate base contacts are each arranged alternately and parallel to one another and wherein the centre-to-centre distance (W_{c}, W_{b}) between adjacent emitter and base regions is less than the centre-to-centre distance (W_{E}, W_{B}) between adjacent emitter and base contacts.

14. Rear-contact solar cell according to claim 11, wherein elongate emitter contacts traverse elongate base regions and wherein the elongate base regions are insulated from the elongate emitter contacts traversing them by an electrically insulating layer.

15. Rear-contact solar cell according to claim 11, wherein elongate base contacts traverse elongate emitter regions and wherein the elongate emitter regions are insulated from the elongate base contacts traversing them by an electrically insulating layer.

16. Rear-contact solar cell according to claim 11, wherein an electrical conductivity is higher in the elongate base regions on the rear side surface of the semiconductor substrate than in base regions in the interior of the semiconductor substrate.

17. Rear-contact solar cell according to claim 11, wherein the emitter regions and the base regions are distributed substantially homogeneously along the rear side surface of the semiconductor substrate.

18. Rear-contact solar cell according to claim 11, wherein elongate base regions protrude into regions covered by an emitter busbar.

19. Rear-contact solar cell according to claim 11, wherein elongate emitter regions protrude into regions covered by a base busbar.

20. Method for producing a solar cell, including:
providing a semiconductor substrate;
forming elongate base regions on the rear side surface of the semiconductor substrate, the base regions having a base semiconductor type;
forming elongate emitter regions on a rear side surface of the semiconductor substrate, the emitter regions having an emitter semiconductor type opposite to the base semiconductor type;
forming elongate emitter contacts transversely to the elongate emitter regions for electrically contacting the emitter regions;
forming elongate base contacts transversely to the elongate base regions for electrically contacting the base regions;
wherein the elongate emitter regions have smaller structural widths than the elongate emitter contacts and wherein the elongate base regions have smaller structural widths than the elongate base contacts.
